(19) United States
(12) Patent Application Publication
(10) Pub. No.: US 2025/0267941 A1
(43) Pub. Date: Aug. 21, 2025

(54) DRIVE CIRCUIT SUBSTRATE AND METHOD OF MANUFACTURING DRIVE CIRCUIT SUBSTRATE

(71) Applicants: Sharp Display Technology Corporation, Kameyama City (JP); SHARP KABUSHIKI KAISHA, Sakai City (JP)

(72) Inventors: Yoshinobu NAKAMURA, Kameyama City (JP); TADAYOSHI MIYAMOTO, Sakai City (JP)

(21) Appl. No.: 19/021,815

(22) Filed: Jan. 15, 2025

(30) Foreign Application Priority Data
Feb. 16, 2024 (JP) 2024-022199

(51) Int. Cl. H10D 86/40; H10D 62/80; H10D 86/01

(52) U.S. Cl. CPC H10D 86/425; H10D 86/0221; H10D 86/481; H10D 62/875; H10D 86/423; H10D 86/451

(57) ABSTRACT

A drive circuit substrate includes a unit drive circuit including a first transistor including a first semiconductor layer having a first channel region, and a first source region and a first drain region that contain a P-type impurity, a first insulating layer that is provided on the first semiconductor layer, a first-gate-electrode-combined first facing electrode that contains an oxide semiconductor and a conductor impurity and that is provided on the first insulating layer such that the first-gate-electrode-combined first facing electrode overlaps the first channel region in plan view, a first interlayer insulating film that is provided on the first-gate-electrode-combined first facing electrode, a second facing electrode that is provided on the first interlayer insulating film such that the second facing electrode overlaps the first-gate-electrode-combined first facing electrode in plan view, a first drain electrode, a first source electrode, and a holding capacitor.

### BACKGROUND

### 1. Field

The present disclosure relates to a drive circuit substrate and a method of manufacturing a drive circuit substrate.

### 2. Description of the Related Art

In recent years, a drive circuit substrate that includes multiple unit drive circuits including transistors has been frequently used as a pixel circuit for displaying in a display region of a display device or a drive driver that is provided in a non-display region of the display device and that drives the pixel circuit in the field of display devices. The drive circuit substrate can be used in various fields other than the field of display devices such as the fields of 3D printers and fingerprint sensors. For this reason, the research and development of these are extensively carried out.

### SUMMARY

In the description in U.S. Patent Application Publication No. 2015/0055051 and 2015/0053935, a drive circuit substrate that includes multiple unit drive circuits including a drive transistor and a selection transistor is used as a pixel circuit for displaying in a display region of a display device. However, a semiconductor layer that is included in the drive transistor or the selection transistor that is included in the unit drive circuits described in U.S. Patent Application Publication No. 2015/0055051 and 2015/0053935 is only a polycrystalline silicon layer, and a semiconductor layer that is included in the other of the drive transistor or the selection transistor is only an oxide semiconductor layer. Accordingly, the unit drive circuits described in U.S. Patent Application Publication No. 2015/0055051 and 2015/0053935 can efficiently use neither the polycrystalline silicon layer nor the oxide semiconductor layer.

In U.S. Patent Application Publication No. 2015/0055051 and 2015/0053935, there are no contrivances for decreasing the areas of the unit drive circuits and increasing reliability, and it is difficult to ensure high definition and high reliability of the unit drive circuits.

It is desirable to provide a drive circuit substrate and a method of manufacturing a drive circuit substrate that efficiently use a polycrystalline silicon layer and an oxide semiconductor layer and that enable high definition and high reliability of a unit drive circuit to be ensured.

According to an aspect of the disclosure, there is provided a drive circuit substrate including a unit drive circuit including a first transistor including a first semiconductor layer having a first channel region that is a portion of a polycrystalline silicon layer, and a first source region and a first drain region that are formed as regions of the polycrystalline silicon layer different from the first channel region and that contain a P-type impurity, a first insulating layer that is provided on the first semiconductor layer, a first-gate-electrode-combined first facing electrode that contains an oxide semiconductor and a conductor impurity and that is provided on the first insulating layer such that the first-gate-electrode-combined first facing electrode overlaps the first channel region in plan view, a first interlayer insulating film that is provided on the first-gate-electrode-combined first facing electrode, a second facing electrode that is provided on the first interlayer insulating film such that the second facing electrode overlaps the first-gate-electrode-combined first facing electrode in plan view, a first drain electrode that is electrically connected to the first drain region, a first source electrode that is electrically connected to the first source region and the second facing electrode, and a holding capacitor that includes the first facing electrode and the second facing electrode.

According to an aspect of the disclosure, there is provided a method of manufacturing a drive circuit substrate including forming a polycrystalline silicon layer, forming a first insulating layer on the polycrystalline silicon layer, forming a first channel region, a first source region that contains a P-type impurity, and a first drain region that contains the P-type impurity by forming a resist film that has a predetermined shape on the first insulating layer and injecting the P-type impurity into a portion of the polycrystalline silicon layer with the resist film used as a mask, forming a first-gate-electrode-combined first facing electrode, in which after the resist film is removed, a first oxide semiconductor layer is formed on the first insulating layer such that the first oxide semiconductor layer overlaps the first channel region in plan view, and a first interlayer insulating film that contains a conductor impurity is formed on the first insulating layer and the first oxide semiconductor layer, forming a second facing electrode on the first interlayer insulating film such that the second facing electrode overlaps the first-gate-electrode-combined first facing electrode in plan view, forming a first drain electrode that is electrically connected to the first drain region and a first source electrode that is electrically connected to the first source region and the second facing electrode, and forming a unit drive circuit including a first transistor including a holding capacitor that includes the first facing electrode and the second facing electrode.

According to an aspect of the disclosure, there is provided a method of manufacturing a drive circuit substrate including forming a polycrystalline silicon layer, forming a first insulating layer on the polycrystalline silicon layer, forming a first oxide semiconductor layer on the first insulating layer such that the first oxide semiconductor layer overlaps a portion of the polycrystalline silicon layer in plan view and forming a first channel region, a first source region that contains a P-type impurity, and a first drain region that contains the P-type impurity by forming a resist film on the first oxide semiconductor layer and injecting the P-type impurity into a portion other than the portion of the polycrystalline silicon layer with the resist film used as a mask, forming a first-gate-electrode-combined first facing electrode, in which after the resist film is removed, a first interlayer insulating film that contains a conductor impurity is formed on the first insulating layer and the first oxide semiconductor layer, forming a second facing electrode on the first interlayer insulating film such that the second facing electrode overlaps the first-gate-electrode-combined first facing electrode in plan view, forming a first drain electrode that is electrically connected to the first drain region and a first source electrode that is electrically connected to the first source region and the second facing electrode, and forming a unit drive circuit including a first transistor including a holding capacitor that includes the first facing electrode and the second facing electrode.

### BRIEF DESCRIPTION OF THE DRAWINGS

FIG. 1 is a circuit diagram of one of unit drive circuits that are included in a drive circuit substrate according to a first embodiment;

FIG. 2 schematically illustrates a sectional view of the structure of a first transistor that is included in the drive circuit substrate according to the first embodiment;

FIG. 3 is a plan view of the drive circuit substrate according to the first embodiment and schematically illustrates the structure of the drive circuit substrate;

FIG. 4 schematically illustrates a sectional view of the structure of the drive circuit substrate according to the first embodiment;

FIG. 5 illustrates a comparison between the on-off characteristics of the first transistor and a second transistor that are included in the drive circuit substrate according to the first embodiment and the on-off characteristics of a transistor that includes an amorphous silicon semiconductor layer;

FIG. 6 illustrates the I-V characteristics of a second channel region in a second semiconductor layer of the second transistor that is included in the drive circuit substrate according to the first embodiment;

FIG. 7 illustrates the I-V characteristics of a first-gate-electrode-combined first facing electrode of the first transistor that is included in the drive circuit substrate according to the first embodiment and the I-V characteristics of a second source region and a second drain region in the second semiconductor layer of the second transistor;

FIG. 8 illustrates a comparison between the reliability of the first transistor that is included in the drive circuit substrate according to the first embodiment and that is a P-type transistor and the reliability of an N-type transistor in a comparative example;

FIG. 9 illustrates some processes in a method of manufacturing the drive circuit substrate according to the first embodiment;

FIG. 10 illustrates other processes in the method of manufacturing the drive circuit substrate according to the first embodiment;

FIG. 11 illustrates other processes in the method of manufacturing the drive circuit substrate according to the first embodiment;

FIG. 12 illustrates the other process in the method of manufacturing the drive circuit substrate according to the first embodiment;

FIG. 13 illustrates some processes in a method of manufacturing a drive circuit substrate in a first comparative example;

FIG. 14 illustrates some processes in a method of manufacturing a drive circuit substrate according to a second embodiment;

FIG. 15 illustrates other processes in the method of manufacturing the drive circuit substrate according to the second embodiment;

FIG. 16 schematically illustrates a plan view of the structure of the drive circuit substrate in the first comparative example; and

FIG. 17 schematically illustrates a sectional view of the structure of the drive circuit substrate in the first comparative example.

### DESCRIPTION OF THE EMBODIMENTS

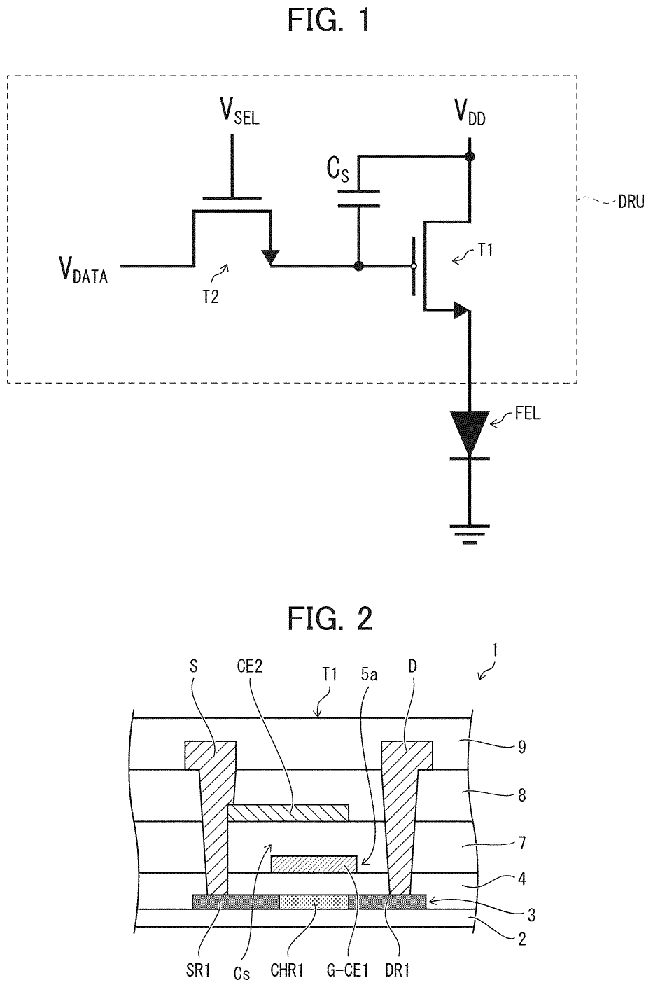

Embodiments of the present disclosure will be described below based on FIG. 1 to FIG. 17. In some cases, for convenience of description below, a component that has a function like to that of a component described according to a certain embodiment is designated by a like reference sign, and the description thereof is omitted.

### First Embodiment

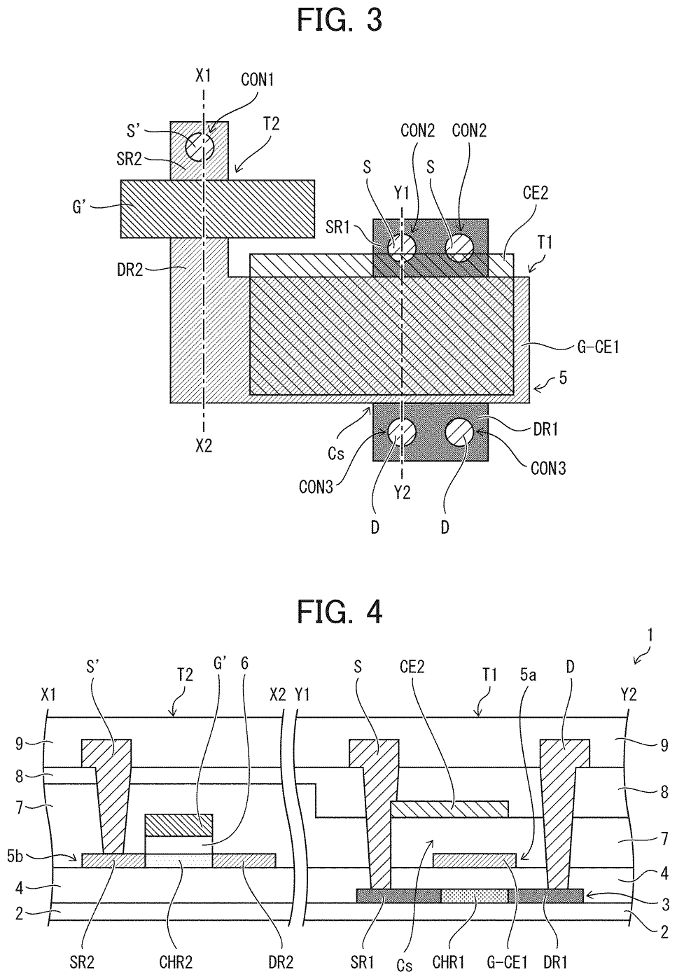

FIG. 1 is a circuit diagram of one of unit drive circuits DRU that are included in a drive circuit substrate 1 according to a first embodiment. FIG. 2 schematically illustrates a sectional view of the structure of a first transistor T1 that is included in the drive circuit substrate 1 according to the first embodiment. FIG. 3 is a plan view of the drive circuit substrate 1 according to the first embodiment and schematically illustrates the structure of the drive circuit substrate 1. In FIG. 3, a barrier layer 2, a first insulating layer 4, a second insulating layer 6, a first interlayer insulating film 7, a second interlayer insulating film 8, and a passivation film 9 are not illustrated. FIG. 4 schematically illustrates a sectional view of the structure of the drive circuit substrate 1 according to the first embodiment taken along a line X1-X2 and a line Y1-Y2 illustrated in FIG. 3.

In a case described by way of example according to the present embodiment, as illustrated in FIG. 1, the unit drive circuits DRU include respective light-emitting elements that serve as functional units FEL that are electrically connected to the unit drive circuits DRU. However, this is not a limitation. Fingerprint sensor units or 3D printer anode electrodes, for example, may be included as the functional units FEL that are electrically connected to the unit drive circuits DRU. For example, the unit drive circuit DRU illustrated in FIG. 1 may be a drive driver that is provided in a non-display region of a display device. In this case, the functional units FEL that are electrically connected to the unit drive circuits DRU may be pixel circuits that are provided in a display region of the display device. In a case described by way of example according to the present embodiment, the light-emitting elements that serve as the functional units FEL are organic light-emitting diodes (OLEDs). However, this is not a limitation. For example, the light-emitting elements may be quantum dot light-emitting diodes (QLEDs) or micro LEDs.

As for the unit drive circuit DRU and the functional unit FEL illustrated in FIG. 1, as illustrated in FIG. 1, FIG. 2, and FIG. 4, a first drain electrode D of the first transistor T1 that is a drive transistor is electrically connected to one of electrodes of the light-emitting element that is the functional unit FEL such as an anode electrode (not illustrated). As illustrated in FIG. 1, FIG. 2, and FIG. 4, a first source electrode S of the first transistor T1 that is the drive transistor is electrically connected to a second facing electrode CE2 of a holding capacitor Cs. As illustrated in FIG. 1, FIG. 2, and FIG. 4, a first-gate-electrode-combined first facing electrode G-CE1 (illustrated in FIG. 2 and FIG. 4) that is a common electrode is provided as a gate electrode of the first transistor T1 and a first facing electrode of the holding capacitor Cs. As illustrated in FIG. 3, the first-gate-electrode-combined first facing electrode G-CE1 is electrically connected to a second drain region DR2 of a second transistor T2 that is a selection transistor. As illustrated in FIG. 1, the first source electrode S of the first transistor T1 is electrically connected to a high-potential power supply voltage line VDD through which a high-potential power supply voltage is supplied, and the other electrode of the light-emitting element that is the functional unit FEL such as a cathode electrode (not illustrated) is electrically connected to a low-potential power supply voltage line through which a low-potential power supply voltage is supplied such as a low-potential power supply voltage line that is grounded. As illustrated in FIG. 1 and FIG. 4, a second source electrode S′ of the second transistor T2 that is the selection transistor is electrically connected to a data signal line VDATA through which a data signal is supplied, and a second gate electrode G′ of the second transistor T2 is electrically connected to a scanning signal line VSEL through which a scanning signal is supplied. According to the present embodiment, as illustrated in FIG. 1, the unit drive circuits DRU include the respective light-emitting elements that are driven with an electric current and that serve as the functional units FEL that are electrically connected to the unit drive circuits DRU. Accordingly, the first transistor T1 that is included in each of the multiple unit drive circuits DRU of the drive circuit substrate 1 and that is the drive transistor may have high current drive ability. The second transistor T2 that is the selection transistor has a role in supplying a voltage corresponding to the data signal to the first transistor T1 with the timing of the scanning signal and changing the voltage of the first transistor T1, and accordingly, the second transistor T2 may have transistor characteristics such that the amount of a leak current is small. In view of this, according to the present embodiment, as illustrated in FIG. 2 and FIG. 4, the first transistor T1 that is the drive transistor includes a first semiconductor layer 3 that has a first channel region CHR1 that is a polycrystalline silicon layer, and the second transistor T2 that is the selection transistor includes a second semiconductor layer 5b that has a second channel region CHR2 that is an oxide semiconductor layer. According to the present embodiment, the first transistor T1 is a P-type transistor that includes the first semiconductor layer 3 that has the first channel region CHR1 that is the polycrystalline silicon layer, and a first source region SR1 and a first drain region DR1 in which P-type impurities are contained in the polycrystalline silicon layer, and accordingly, a change in characteristics (hot carrier degradation) due to the concentration of electric fields at an end of the first drain electrode D facing the first drain region DR1 and the first drain region DR1 is reduced. Accordingly, as for the first transistor T1, the change in characteristics (hot carrier degradation) due to the concentration of electric fields can be reduced even through a lightly doped drain LDD is not additionally provided between the first channel region CHR1 and the first drain region DR1. Accordingly, the size of the first transistor T1 can be reduced, and the drive circuit substrate 1 that enables each unit drive circuit DRU including the first transistor T1 to have high definition can be achieved. As for the first transistor T1 according to the present embodiment, as illustrated in FIG. 2 and FIG. 4, the second facing electrode CE2 of the holding capacitor Cs is provided so as to overlap the first-gate-electrode-combined first facing electrode G-CE1 that is provided such that the first-gate-electrode-combined first facing electrode G-CE1 overlaps the first channel region CHR1 in plan view, and the second facing electrode CE2 and a first source electrode S are electrically connected to each other by using a contact hole for electrically connecting the first source electrode S and the first source region SR1 to each other. Accordingly, the size of the first transistor T1 can be further reduced, and the drive circuit substrate 1 that enables each unit drive circuit DRU including the first transistor T1 to have higher definition can be achieved. The reliability of the P-type transistor is higher than the reliability of an N-type transistor as described later, and accordingly, the use of the P-type transistor as the first transistor T1 according to the present embodiment achieves the drive circuit substrate 1 that enables the high reliability of each unit drive circuit to be ensured.

In the case where the P-type transistor is used as the first transistor T1 that is included in each unit drive circuit DRU as described above, an input signal that is inputted into the first transistor T1 from the outside is changed into a signal for the P-type transistor, and the structure of an IC chip that outputs the input signal that is inputted into the first transistor T1 is changed. In view of this, as for the unit drive circuits DRU that are included in the drive circuit substrate 1 according to the present embodiment, input signals from the outside such as a data signal from the data signal line VDATA and a scanning signal from the scanning signal line VSEL are inputted into only the second transistor T2 that is an N-type transistor and that includes the second semiconductor layer 5b that has the second channel region CHR2 that is the oxide semiconductor layer, and a second source region SR2 and the second drain region DR2 that contain conductor impurities. Accordingly, as for the unit drive circuits DRU that are included in the drive circuit substrate 1, input signals that are inputted into the unit drive circuits DRU from the outside and the structure of the IC chip that outputs the input signals that are inputted into the unit drive circuits DRU may not be changed into those for the P-type transistor.

As illustrated in FIG. 2 and FIG. 4, the first transistor T1 that is included in each unit drive circuit DRU of the drive circuit substrate 1 includes the first semiconductor layer 3 that has the first channel region CHR1 that is a portion of the polycrystalline silicon layer, and the first source region SR1 and the first drain region DR1 that are formed as regions of the polycrystalline silicon layer different from the first channel region CHR1 and that contain the P-type impurities, the first insulating layer 4 that is provided on the first semiconductor layer 3, the first-gate-electrode-combined first facing electrode G-CE1 that is provided on the first insulating layer 4 such that the first-gate-electrode-combined first facing electrode G-CE1 overlaps the first channel region CHR1 in plan view and that is a second semiconductor layer 5a that contains an oxide semiconductor (according to the present embodiment, an In—Ga—Zn—O semiconductor) and conductor impurities, the first interlayer insulating film 7 that is provided on the first-gate-electrode-combined first facing electrode G-CE1, the second facing electrode CE2 that is provided on the first interlayer insulating film 7 such that the second facing electrode CE2 overlaps the first-gate-electrode-combined first facing electrode G-CE1 in plan view, the first drain electrode D that is electrically connected to the first drain region DR1, the first source electrode S that is electrically connected to the first source region SR1 and the second facing electrode CE2, and the holding capacitor Cs that includes the first facing electrode G-CE1 and the second facing electrode CE2. In a case described by way of example according to the present embodiment, the drive circuit substrate 1 includes the unit drive circuits DRU each of which includes the first transistor T1 and the second transistor T2 but is not limited thereto, provided that the drive circuit substrate 1 includes the unit drive circuits DRU each of which includes the first transistor T1. Each first transistor T1 that is included in the drive circuit substrate 1 includes the first semiconductor layer 3 that is the polycrystalline silicon layer and the first-gate-electrode-combined first facing electrode G-CE1 that is an oxide semiconductor layer that contains conductor impurities, and accordingly, the drive circuit substrate 1 that efficiently uses the polycrystalline silicon layer and the oxide semiconductor layer can be achieved. Each first transistor T1 that is included in the drive circuit substrate 1 is the P-type transistor that includes the first semiconductor layer 3 that has the first channel region CHR1 that is the polycrystalline silicon layer, and the first source region SR1 and the first drain region DR1 in which the P-type impurities are contained in the polycrystalline silicon layer. Accordingly, the size can be reduced, and the high reliability can be ensured as described above. Accordingly, the drive circuit substrate 1 that enables the high definition and high reliability of the unit drive circuits DRU to be ensured can be achieved.

As illustrated in FIG. 3 and FIG. 4, each unit drive circuit DRU that is included in the drive circuit substrate 1 further includes the second transistor T2 that is the N-type transistor in addition to the first transistor T1 that is the P-type transistor described above. As illustrated in FIG. 4, the second transistor T2 includes the second semiconductor layer 5b that has the second channel region CHR2, the second source region SR2, and the second drain region DR2, the second insulating layer 6 that is provided on the second channel region CHR2 such that the second insulating layer 6 overlaps only the second channel region CHR2 in plan view, the second gate electrode G′ that is provided on the second insulating layer 6 such that the second gate electrode G′ overlaps the second channel region CHR2 in plan view, and the second source electrode S′ that is electrically connected to the second source region SR2. The second channel region CHR2 is formed in the same layer as the first-gate-electrode-combined first facing electrode G-CE1 and is composed of the same material (according to the present embodiment, an In—Ga—Zn—O semiconductor) as the oxide semiconductor that is contained in the first-gate-electrode-combined first facing electrode G-CE1. The second source region SR2 and the second drain region DR2 are formed in the same layer as the first-gate-electrode-combined first facing electrode G-CE1 and are composed of the same material (according to the present embodiment, an In—Ga—Zn—O semiconductor and conductor impurities) as the first-gate-electrode-combined first facing electrode G-CE1. That is, as illustrated in FIG. 3, the drive circuit substrate 1 includes second semiconductor layers 5 that contain an oxide semiconductor, and as illustrated in FIG. 4, the second semiconductor layers 5 include the second semiconductor layer 5a that is included in the first transistor T1 and the second semiconductor layer 5b that is included in the second transistor T2. The second semiconductor layer 5a that is included in the first transistor T1 contains the conductor impurities and the oxide semiconductor and functions as the first-gate-electrode-combined first facing electrode G-CE1. The second source region SR2 and the second drain region DR2 in the second semiconductor layer 5b that is included in the second transistor T2 contain the conductor impurities and the oxide semiconductor as in the second semiconductor layer 5a that is included in the first transistor T1, and the second channel region CHR2 in the second semiconductor layer 5b that is included in the second transistor T2 is composed of the same material as the oxide semiconductor (according to the present embodiment, an In—Ga—Zn—O semiconductor) that is contained in the first-gate-electrode-combined first facing electrode G-CE1.

The second transistor T2 that is included in each unit drive circuit DRU that is included in the drive circuit substrate 1 has the second channel region CHR2 composed of the same material as the oxide semiconductor (according to the present embodiment, an In—Ga—Zn—O semiconductor) that is contained in the first-gate-electrode-combined first facing electrode G-CE1 as described above. Accordingly, an effect of electric field relaxation can be exerted, that is, an off-current Ioff that is generated when the second transistor T2 is off can be reduced, and a lightly doped drain LDD may not be additionally provided as described later. This enables each unit drive circuit DRU that includes the first transistor T1 and the second transistor T2 to be formed with a reduced size and enables each unit drive circuit DRU that includes the first transistor T1 and the second transistor T2 to have high definition, as for the drive circuit substrate 1.

The first transistor T1 that is the drive transistor and that is included in each unit drive circuit DRU that is included in the drive circuit substrate 1 includes the first semiconductor layer 3 that has the first channel region CHR1 that is the polycrystalline silicon layer, and the second transistor T2 that is the selection transistor includes the second semiconductor layer 5b that has the second channel region CHR2 that is the oxide semiconductor layer as described above. Accordingly, the first transistor T1 has the high current drive ability, and the second transistor T2 has the transistor characteristics such that the amount of a leak current is small, as described above.

Each unit drive circuit DRU that is included in the drive circuit substrate 1 includes the second transistor T2 that is the N-type transistor as described above. Accordingly, in the case where external input signals are inputted into only the second transistor T2 that is the N-type transistor, the input signals that are inputted into the unit drive circuits DRU from the outside and the structure of the IC chip that outputs the input signal that is inputted into the unit drive circuits DRU may not be changed into those for the P-type transistor.

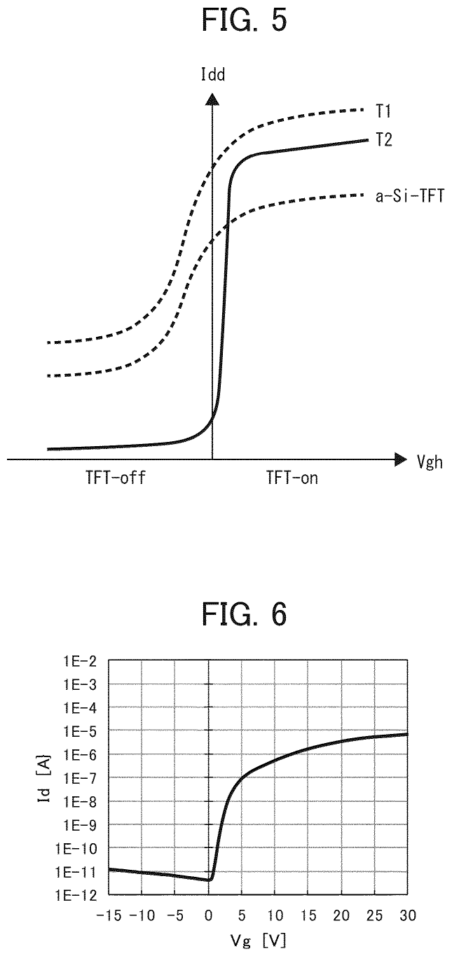

FIG. 5 illustrates a comparison between the on-off characteristics of the first transistor T1 and the second transistor T2 that are included in the drive circuit substrate 1 according to the first embodiment and the on-off characteristics of a transistor that includes an amorphous silicon semiconductor layer.

In a case described by way of example according to the present embodiment, the first channel region CHR1 that is the polycrystalline silicon layer and that the first transistor T1 that is the drive transistor has is composed of polysilicon formed at a low temperature, and the second channel region CHR2 that is the oxide semiconductor layer and that the second transistor T2 that is the selection transistor has is composed of an In—Ga—Zn—O semiconductor, but this is not a limitation. The first channel region CHR1 that is the polycrystalline silicon layer and that the first transistor T1 that is the drive transistor has may be composed of, for example, polysilicon formed at a high temperature, and the second channel region CHR2 that is the oxide semiconductor layer and that the second transistor T2 that is the selection transistor has may be composed of, for example, an oxide semiconductor other than an In—Ga—Zn—O semiconductor.

As illustrated in FIG. 5, the mobility of the first transistor T1 that is the drive transistor and that has the first channel region CHR1 that is the polycrystalline silicon layer during TFT-on, that is, the value of an electric current Idd during TFT-on is greater than the mobility of the second transistor T2 that is the selection transistor and that has the second channel region CHR2 that is the oxide semiconductor layer and a transistor in a comparative example that has a channel region that is the amorphous silicon semiconductor layer during TFT-on, that is, the value of the electric current Idd during TFT-on, and the first transistor T1 that is the drive transistor has high current drive ability.

As illustrated in FIG. 5, the mobility of the second transistor T2 that is the selection transistor and that has the second channel region CHR2 that is the oxide semiconductor layer during TFT-on, that is, the value of the electric current Idd during TFT-on is about 20 times to 50 times greater than that of the transistor in the comparative example that has the channel region that is the amorphous silicon semiconductor layer. The mobility of the second transistor T2 that is the selection transistor and that has the second channel region CHR2 that is the oxide semiconductor layer during TFT-off, that is, the value of the off-current Ioff during TFT-off is about 1/100 times that of the transistor in the comparative example that has the channel region that is the amorphous silicon semiconductor layer and is about 1/1000 times that of the first transistor T1 that is the drive transistor and that has the first channel region CHR1 that is the polycrystalline silicon layer. That is, the second transistor T2 that is the selection transistor and that has the second channel region CHR2 that is the oxide semiconductor layer when being off has a resistance value that is about 100 times that of the transistor in the comparative example that has the channel region that is the amorphous silicon semiconductor layer and that is about 1000 times that of the first transistor T1 that is the drive transistor and that has the first channel region CHR1 that is the polycrystalline silicon layer. Ion/off of the second transistor T2 that is the selection transistor and that has the second channel region CHR2 that is the oxide semiconductor layer as described above, that is, the ratio between the amount of the electric current during TFT-on and the amount of the electric current during TFT-off is 109 or more, and Ion/Ioff of the first transistor T1 that is the drive transistor and that has the first channel region CHR1 that is the polycrystalline silicon layer is 107, and Ion/Ioff of the transistor in the comparative example that has the channel region that is the amorphous silicon semiconductor layer is 106. Accordingly, the second transistor T2 that is the selection transistor and that has the second channel region CHR2 that is the oxide semiconductor layer has the transistor characteristics such that the amount of a leak current is small.

As illustrated in FIG. 2 and FIG. 4, the first semiconductor layer 3 is provided on the barrier layer 2. The barrier layer 2 inhibits a foreign substance such as water or oxygen from entering the first transistor T1 and the second transistor T2 and can be composed of a silicon oxide film, a silicon nitride film, or a silicon oxynitride film that is formed by using, for example, a CVD method or a multilayer film of these. The film thickness of the barrier layer 2 is not particularly limited provided that the foreign substance such as water or oxygen can be inhibited from entering the first transistor T1 and the second transistor T2.

As illustrated in FIG. 3, the second drain region DR2 in the second transistor T2 that is included in the drive circuit substrate 1 and the first-gate-electrode-combined first facing electrode G-CE1 in the first transistor T1 may be connected to each other. With this structure, a connection contact hole for electrically connecting the second drain region DR2 that is included in the second transistor T2 and the first-gate-electrode-combined first facing electrode G-CE1 that is included in the first transistor T1 to each other may not be provided, each unit drive circuit DRU that includes the first transistor T1 and the second transistor T2 can be formed with a reduced size, and each unit drive circuit DRU that includes the first transistor T1 and the second transistor T2 can have high definition, as for the drive circuit substrate 1.

The first interlayer insulating film 7 illustrated in FIG. 4 contains, for example, hydrogen that serves as conductor impurities. In the case where the first interlayer insulating film 7 that contains, for example, hydrogen that is the conductor impurities is formed, the hydrogen that is the conductor impurities in the first interlayer insulating film 7, for example, spreads to the second semiconductor layer 5a that is included in the first transistor T1 and that contains the oxide semiconductor in direct contact with the first interlayer insulating film 7 and to the second source region SR2 and the second drain region DR2 in the second semiconductor layer 5b that is included in the second transistor T2, and the second source region SR2 and the second drain region DR2 in the second semiconductor layer 5b that is included in the second transistor T2 and the first-gate-electrode-combined first facing electrode G-CE1 that is the second semiconductor layer 5a that is included in the first transistor T1 are made conductive. Accordingly, as illustrated in FIG. 4, the first interlayer insulating film 7 that contains, for example, hydrogen that is the conductor impurities may be provided on the second source region SR2, the second drain region DR2, and the first-gate-electrode-combined first facing electrode G-CE1 and may be in contact with the second source region SR2, the second drain region DR2, and the first-gate-electrode-combined first facing electrode G-CE1, and the first interlayer insulating film 7 that contains, for example, hydrogen that is the conductor impurities may not be in contact with the second channel region CHR2, as for the drive circuit substrate 1. As for the drive circuit substrate 1, an interlayer insulating film that contains, for example, hydrogen that is the conductor impurities is used as the first interlayer insulating film 7, the first interlayer insulating film 7 is provided so as to be in direct contact with portions to be conductive in an oxide semiconductor layer as described above for making the oxide semiconductor layer conductive. Accordingly, conductor impurities may not be added into the oxide semiconductor layer.

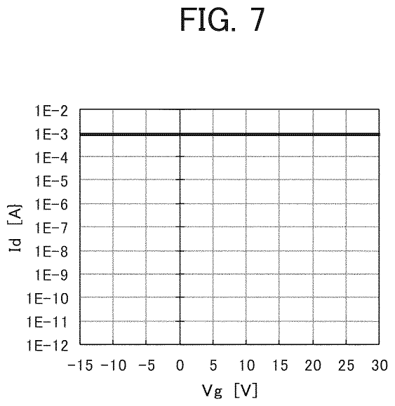

FIG. 6 illustrates the I-V characteristics of the second channel region CHR2 in the second semiconductor layer 5b of the second transistor T2 that is included in the drive circuit substrate 1 according to the first embodiment. FIG. 7 illustrates the I-V characteristics of the first-gate-electrode-combined first facing electrode G-CE1 of the first transistor T1 that is included in the drive circuit substrate 1 according to the first embodiment and the I-V characteristics of the second source region SR2 and the second drain region DR2 in the second semiconductor layer 5b of the second transistor T2.

The second insulating layer 6 illustrated in FIG. 4 may be a silicon oxide film, and the first interlayer insulating film 7 that contains, for example, hydrogen that is the conductor impurities illustrated in FIG. 4 may be a single-layer film composed of silicon nitride or a multilayer film that includes a silicon nitride film that serves as a bottom layer.

As for the second semiconductor layer 5b of the second transistor T2, as illustrated in FIG. 4, the second channel region CHR2 that contains the oxide semiconductor is in contact with the second insulating layer 6 that is the silicon oxide film, and the second channel region CHR2 that contains the oxide semiconductor is oxidized by the second insulating layer 6 that is the silicon oxide film. Accordingly, as illustrated in FIG. 6, the second channel region CHR2 that contains the oxide semiconductor has resistance higher than that of the first-gate-electrode-combined first facing electrode G-CE1, the second drain region DR2, and the second source region SR2 that contain the oxide semiconductor that is made conductive.

According to the present embodiment, a multilayer film in which a lower layer is a silicon nitride film, and an upper layer is a silicon oxide film is used as the first interlayer insulating film 7 that contains, for example, hydrogen that is the conductor impurities illustrated in FIG. 4. According to the present embodiment, the use of the multilayer film that includes the silicon nitride film that contains, for example, hydrogen that is the conductor impurities as the bottom layer enables the silicon nitride film that contains, for example, hydrogen that is the conductor impurities to reduce the oxide semiconductor that is contained in the second source region SR2, the second drain region DR2, and the first-gate-electrode-combined first facing electrode G-CE1 and to make the oxide semiconductor conductive. As illustrated in FIG. 7, the second source region SR2, the second drain region DR2, and the first-gate-electrode-combined first facing electrode G-CE1 that contain the conductive oxide semiconductor have resistance lower than that of the second channel region CHR2 that contains the oxide semiconductor.

In a case described by way of example according to the present embodiment, the multilayer film that includes the silicon nitride film is used as the bottom layer. However, a film other than the silicon nitride film may be used, provided that the film contains hydrogen in a predetermined amount or more and can supply hydrogen to the oxide semiconductor, that is, can reduce the oxide semiconductor. Accordingly, the first interlayer insulating film 7 that contains, for example, hydrogen that is the conductor impurities illustrated in FIG. 4 may be a single-layer film composed of silicon nitride, silicon oxynitride, or silicon oxide or a multilayer film that includes two or more films among a silicon nitride film, a silicon oxynitride film, and a silicon oxide film.

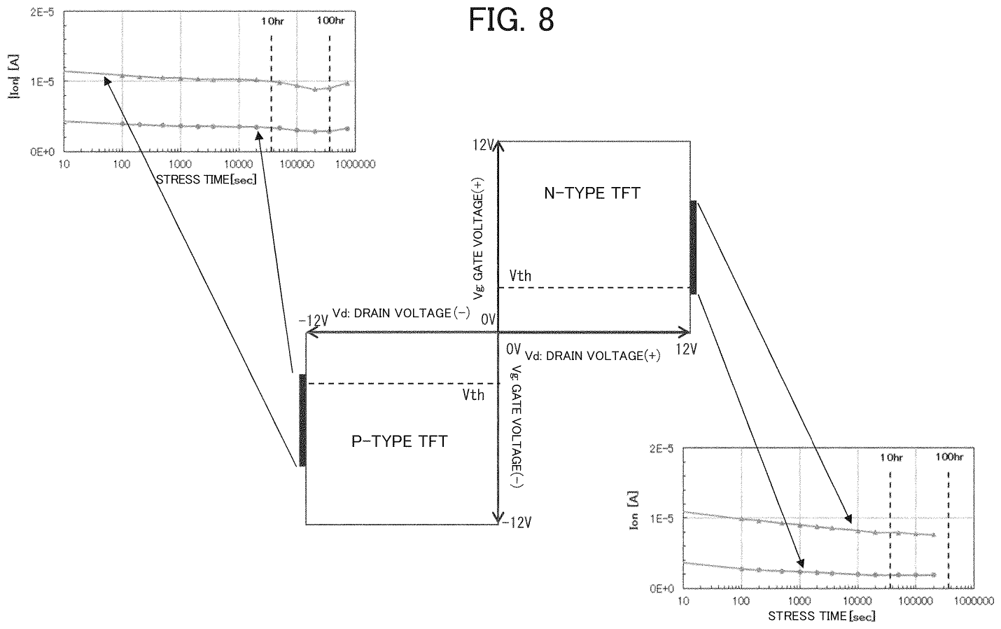

FIG. 8 illustrates a comparison between the reliability of the first transistor that is included in the drive circuit substrate 1 according to the first embodiment and that is the P-type transistor and the reliability of an N-type transistor in the comparative example.

As illustrated in FIG. 8, two different kinds of predetermined voltages are applied to the first transistor that is included in the drive circuit substrate according to the first embodiment and that is the P-type transistor and the N-type transistor in the comparative example, two different kinds of current stresses are applied thereto, and the degree of degradation thereof is evaluated. As illustrated in FIG. 8, it is confirmed that the degree of degradation of the first transistor that is included in the drive circuit substrate according to the first embodiment and that is the P-type transistor, that is, a change in a current amount for a time (for example, 10 hours or more) during which a stress current flows is lower than that of the N-type transistor in the comparative example in response to both of the two different kinds of current stresses. It is thought that this is greatly affected by a difference in carriers (electrons and holes) between the P-type transistor and the N-type transistor. In the case of the P-type transistor, the amount of generated heat itself is smaller than that in the case of the N-type transistor.

In the perspective of the reduced size and reliability of the transistor as described above, the P-type transistor is better than the N-type transistor, and accordingly, the P-type transistor is used as the first transistor that is included in the drive circuit substrate 1 according to the present embodiment.

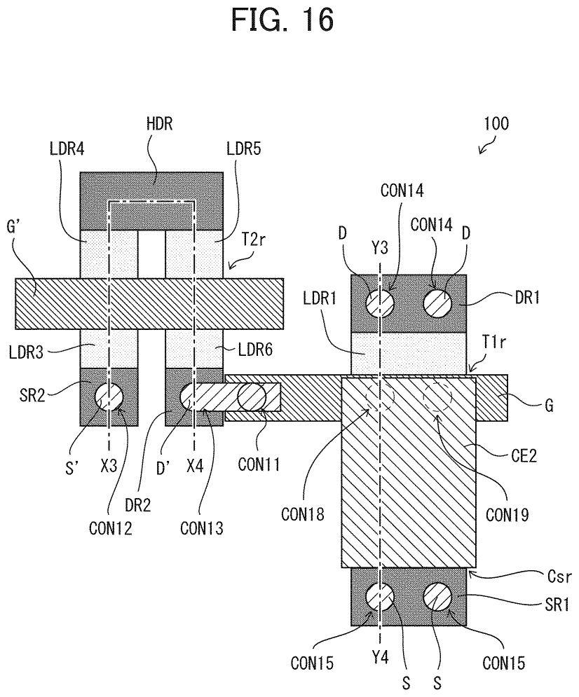

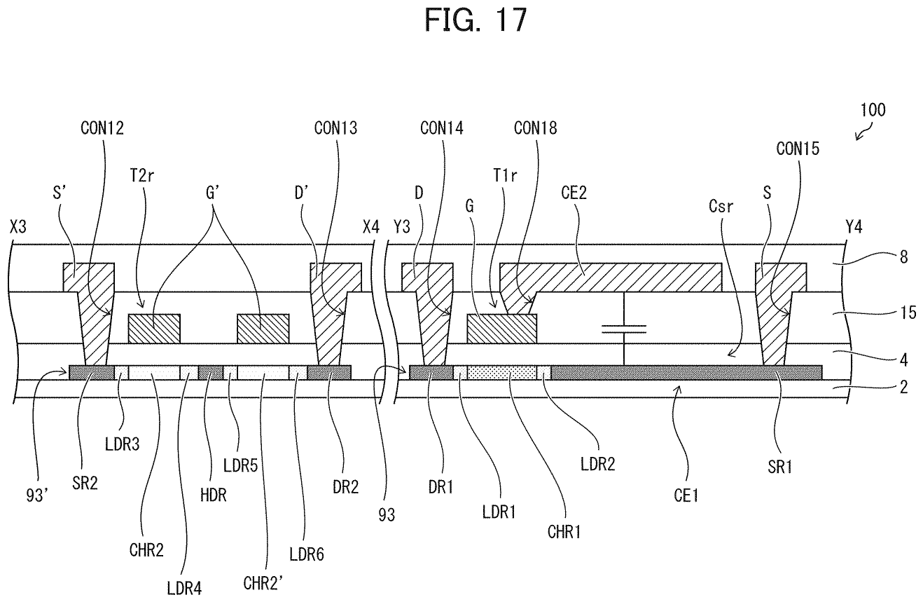

FIG. 16 schematically illustrates a plan view of the structure of a drive circuit substrate 100 in a first comparative example. In FIG. 16, the barrier layer 2, the first insulating layer 4, an interlayer insulating film 15, and the passivation film 9 are not illustrated. FIG. 17 schematically illustrates a sectional view of the structure of the drive circuit substrate 100 in the first comparative example taken along a line X3-X4 and a line Y3-Y4 illustrated in FIG. 16.

As illustrated in FIG. 16 and FIG. 17, the drive circuit substrate 100 in the first comparative example includes a unit drive circuit DRU that includes a first transistor T1r that includes a holding capacitor Csr that includes a first facing electrode CE1 and a second facing electrode CE2 and a second transistor T2r that includes a second gate electrode G′ that has a double structure. The first transistor T1r includes a first semiconductor layer 93 that has a first channel region CHR1 that is a portion of a polycrystalline silicon layer and a first source region SR1 and a first drain region DR1 that are formed as regions of the polycrystalline silicon layer different from the first channel region CHR1 and that contain impurities. Also, the second transistor T2r includes a second semiconductor layer 93′ that has second channel regions CHR2 and CHR2′ that are portions of the polycrystalline silicon layer, a second source region SR2 and a second drain region DR2 that are formed as regions of the polycrystalline silicon layer different from the second channel regions CHR2 and CHR2′ and that contain impurities, and a highly doped region HDR. The first transistor T1r includes a first drain electrode D that is electrically connected to the first drain region DR1 with a contact hole CON14 interposed therebetween and a first source electrode S that is electrically connected to the first source region SR1 with a contact hole CON15 interposed therebetween. The second transistor T2r includes a second source electrode S′ that is electrically connected to the second source region SR2 with a contact hole CON12 interposed therebetween and a second drain electrode D′ that is electrically connected to the second drain region DR2 with a contact hole CON13 interposed therebetween. The second drain region DR2 of second transistor T2r and the gate electrode G of the first transistor T1r are connected by the second drain electrode D′ via a contact hole CON 11.

In the case of the first transistor T1r that is included in the drive circuit substrate 100 in the first comparative example, as illustrated in FIG. 16 and FIG. 17, a first gate electrode G and the second facing electrode CE2 are provided in different layers. Accordingly, as for the drive circuit substrate 100 in the first comparative example, contact holes CON18 and CON19 for electrically connecting the first gate electrode G and the second facing electrode CE2 to each other are provided in the interlayer insulating film 15. The area of the first transistor T1r that is included in the drive circuit substrate 100 in the first comparative example in which the contact holes CON18 and CON19, which may not be provided for the drive circuit substrate 1 according to the first embodiment, are provided is larger than the area of the first transistor T1 that is included in the drive circuit substrate 1 according to the first embodiment as described above For this reason, as for the drive circuit substrate 100 in the first comparative example, it is difficult for the unit drive circuit DRU to have high definition unlike the drive circuit substrate 1 according to the first embodiment.

As illustrated in FIG. 16 and FIG. 17, the first transistor T1r that is included in the drive circuit substrate 100 in the first comparative example has the first channel region CHR1 that is the polycrystalline silicon layer, and the first drain region DR1 and the first source region SR1 that are the polycrystalline silicon layer that contains N-type impurities, and the second transistor T2r has the second channel regions CHR2 and CHR2′ that are the polycrystalline silicon layer, and the second drain region DR2 and the second source region SR2 that are the polycrystalline silicon layer that contains N-type impurities. Accordingly, as for the first transistor T1r, a lightly doped region LDR1 for exerting the effect of electric field relaxation is additionally provided between the first channel region CHR1 and the first drain region DR1. Similarly, as for the second transistor T2r, a lightly doped region LDR6 and a lightly doped region LDR4 for exerting the effect of electric field relaxation are additionally provided between the second channel region CHR2′ and the second drain region DR2 and between the second channel region CHR2 and the highly doped region HDR. The areas of the first transistor T1r and the second transistor T2r that are included in the drive circuit substrate 100 in the first comparative example in which a lightly doped drain LDD, which may not be provided for the drive circuit substrate 1 according to the first embodiment, is provided is larger than the areas of the first transistor T1 and the second transistor T2 that are included in the drive circuit substrate 1 according to the first embodiment. For this reason, as for the drive circuit substrate 100 in the first comparative example, it is difficult for the unit drive circuit DRU to have high definition unlike the drive circuit substrate 1 according to the first embodiment. In the case of the first transistor T1r that is included in the drive circuit substrate 100 in the first comparative example, the lightly doped region LDR1 is provided for the drain, and a lightly doped region LDR2 is provided for the source. In the case of the second transistor T2r that is included in the drive circuit substrate 100 in the first comparative example, the lightly doped regions LDR4 and LDR6 are provided for the drain, and lightly doped regions LDR3 and LDR5 are provided for the source.

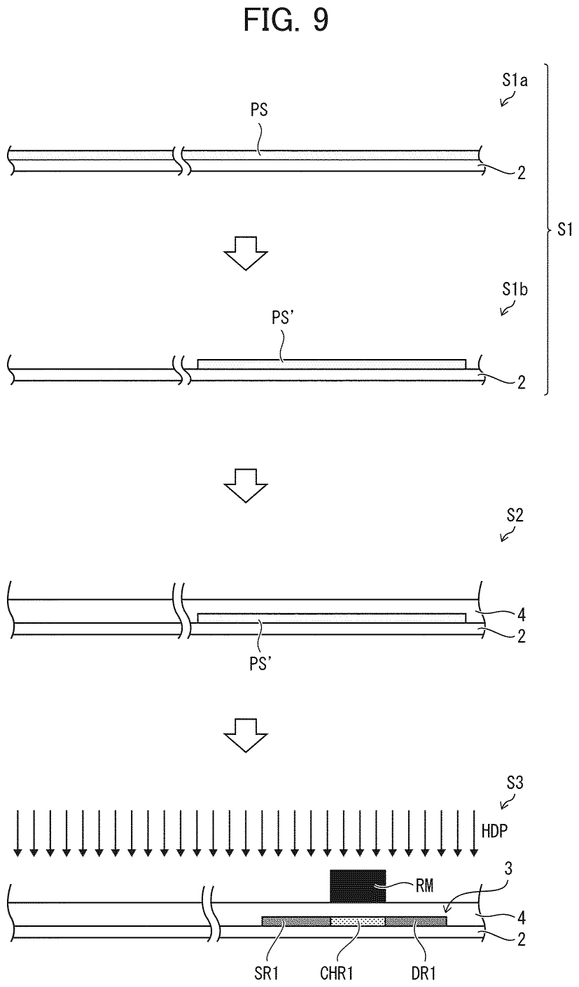

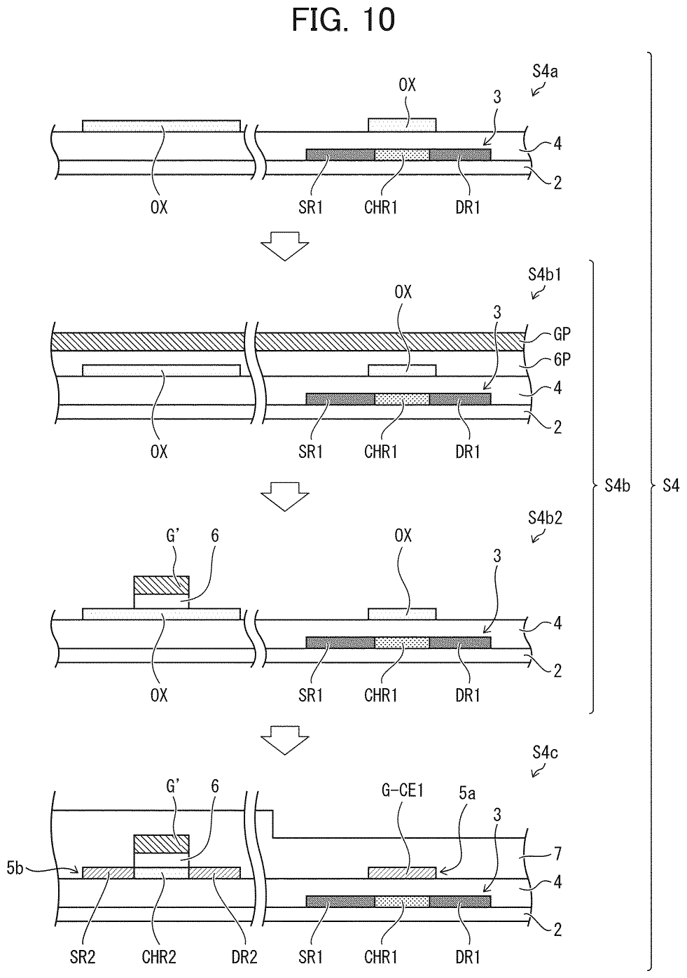

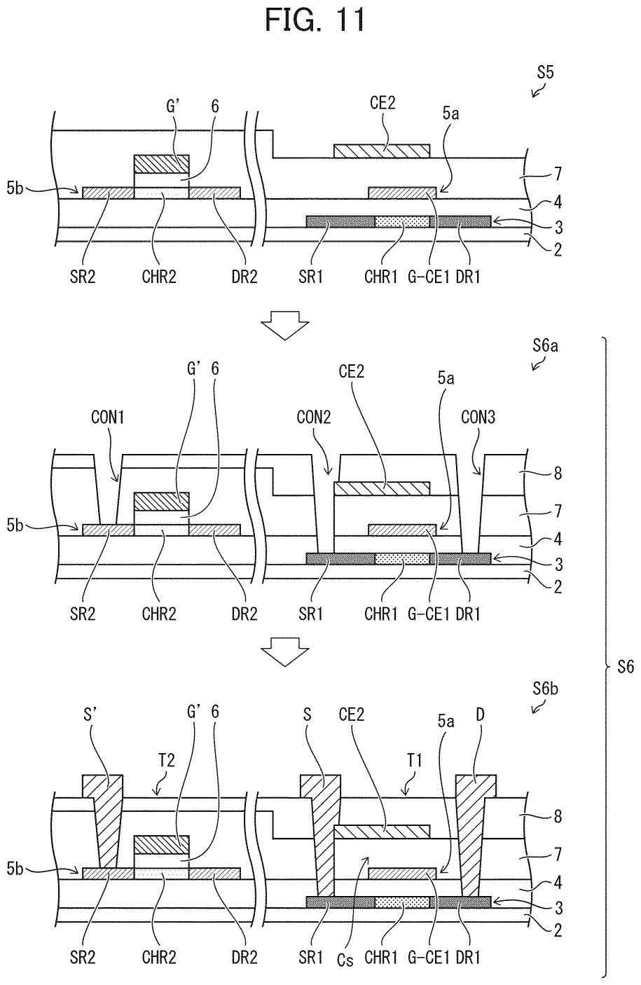

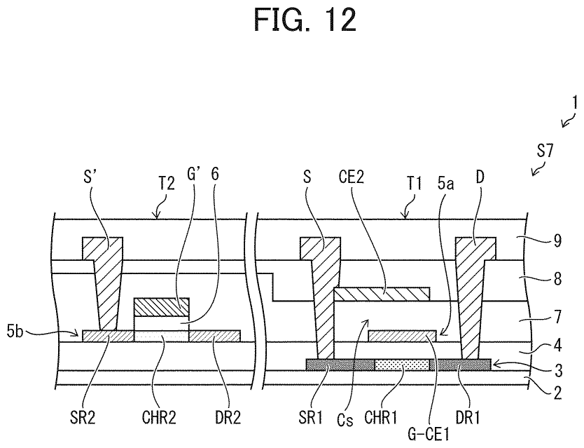

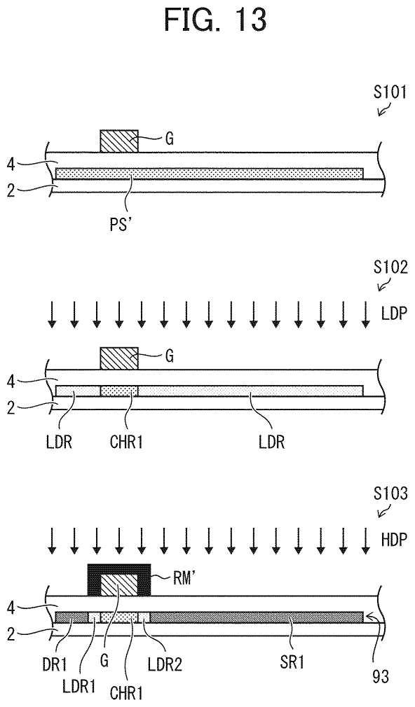

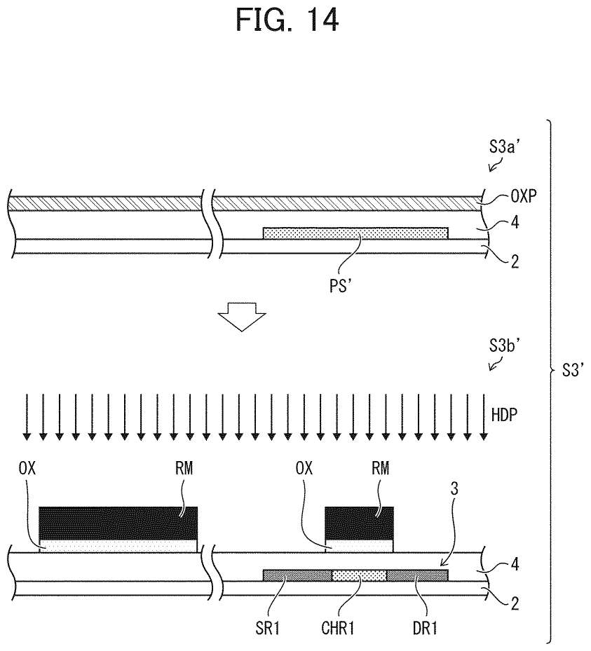

FIG. 9 illustrates some processes in a method of manufacturing the drive circuit substrate 1 according to the first embodiment. FIG. 10 illustrates other processes in the method of manufacturing the drive circuit substrate 1 according to the first embodiment. FIG. 11 illustrates other processes in the method of manufacturing the drive circuit substrate 1 according to the first embodiment. FIG. 12 illustrates the other process in the method of manufacturing the drive circuit substrate 1 according to the first embodiment. FIG. 13 illustrates some processes in a method of manufacturing the drive circuit substrate 100 in the first comparative example.

As illustrated in FIG. 9, the method of manufacturing the drive circuit substrate 1 according to the first embodiment includes a first step S1 at which a polycrystalline silicon layer PS′ is formed on the barrier layer 2, a second step S2 at which the first insulating layer 4 is formed on the polycrystalline silicon layer PS′, and a third step S3 at which a resist film RM that has a predetermined shape is formed on the first insulating layer 4, the P-type impurities are injected into portions of the polycrystalline silicon layer PS′ with the resist film RM used as a mask, and consequently, the first semiconductor layer 3 that has the first channel region CHR1, the first source region SR1 that contains the P-type impurities, and the first drain region DR1 that contains the P-type impurities is formed. The first step S1 illustrated in FIG. 9 includes a step S1a at which annealing (heat treatment) for dehydrogenation is performed at, for example, about 450° C. after an amorphous silicon layer is formed on the barrier layer 2, an excimer laser process is subsequently performed at a relatively low temperature, and a polysilicon film PS that is formed at a low temperature is obtained, and a step S1b at which the polysilicon film PS is etched by using a resist film, and consequently, the polycrystalline silicon layer PS′ in the form of an island is formed on the barrier layer 2. According to the present embodiment, the polycrystalline silicon layer PS′ in the form of an island is formed with, for example, a film thickness of about 40 nm but is not limited thereto. At the second step S2 illustrated in FIG. 9, the first insulating layer 4 having a film thickness of about 85 nm can be obtained, for example, in a manner in which annealing (heat treatment) is performed after a silicon oxide film is formed. At the second step S2 illustrated in FIG. 9, the first insulating layer 4 is formed in addition to the polycrystalline silicon layer PS′ in the form of an island. At the third step S3 illustrated in FIG. 9, injection HDP of the P-type impurities at a high concentration is performed with the resist film RM used as a mask, and consequently, the first channel region CHR1 that is protected by the resist film RM and that contains no P-type impurities, and the first source region SR1 and the first drain region DR1 that have a higher P-type impurities concentration than that of the first channel region CHR1 and that contain the P-type impurities at the high concentration are formed. According to the present embodiment, the first channel region CHR1 is composed of, for example, polysilicon that is a semiconductor that contains no P-type impurities, and the first source region SR1 and the first drain region DR1 that contain the P-type impurities are formed in a manner in which the P-type impurities are injected into polysilicon that is a semiconductor that contains no P-type impurities. According to the present embodiment, the first source region SR1 and the first drain region DR1 that contain the P-type impurities are formed in a manner in which B (boron ions), for example, is injected as the P-type impurities but are not limited thereto, provided that P-type impurities are injected.

As illustrated in FIG. 10, the method of manufacturing the drive circuit substrate 1 according to the first embodiment further includes a fourth step S4 at which the first-gate-electrode-combined first facing electrode G-CE1 is formed, and the fourth step S4 includes an oxide semiconductor layer formation step S4a at which a first oxide semiconductor layer OX is formed on the first insulating layer 4 so as to overlap the first channel region CHR1 in plan view and a first interlayer insulating film formation step S4c at which the first interlayer insulating film 7 that contains the conductor impurities is formed on the first insulating layer 4 and the first oxide semiconductor layer OX after the resist film RM is removed. As illustrated in FIG. 11, the method of manufacturing the drive circuit substrate 1 according to the first embodiment includes a fifth step S5 at which the second facing electrode CE2 is formed on the first interlayer insulating film 7 so as to overlap the first-gate-electrode-combined first facing electrode G-CE1 in plan view and a sixth step S6 at which the first drain electrode D that is electrically connected to the first drain region DR1 and the first source electrode S that is electrically connected to the first source region SR1 and the second facing electrode CE2 are formed, and is a method of forming each unit drive circuit DRU that includes the first transistor T1 that includes the holding capacitor Cs that includes the first facing electrode G-CE1 and the second facing electrode CE2. As illustrated in FIG. 12, the method of manufacturing the drive circuit substrate 1 according to the first embodiment may further include a seventh step S7 at which the passivation film 9 is formed after the sixth step S6 described above.

At the oxide semiconductor layer formation step S4a illustrated in FIG. 10, the first oxide semiconductor layer OX that is included in the first transistor T1 and a second oxide semiconductor layer OX that is included in the second transistor T2 are formed as the same layer on the first insulating layer 4 by using the same material. At a step S4b between the oxide semiconductor layer formation step S4a and the first interlayer insulating film formation step S4c, the second insulating layer 6 is formed, and the second gate electrode G′ is formed on the second insulating layer 6. The step S4b at which the second insulating layer 6 is formed, and the second gate electrode G′ is formed on the second insulating layer 6 includes a step S4b1 at which after an inorganic film 6P a portion of which is to be the second insulating layer 6 is formed on the entire surface of the first insulating layer 4, the first oxide semiconductor layer OX, and the second oxide semiconductor layer OX, a metal film GP a portion of which is to be the second gate electrode G′ is formed on the entire surface, a second insulating layer formation step at which the second insulating layer 6 is formed so as to overlap only a portion of the second oxide semiconductor layer OX that is the second channel region CHR2 and that is included in the second transistor T2 in plan view, and a second gate electrode formation step at which the second gate electrode G′ is formed on the second insulating layer 6 so as to overlap the second channel region CHR2 in plan view. In a case described by way of example according to the present embodiment, the second insulating layer formation step at which the second insulating layer 6 is formed and the second gate electrode formation step are performed as a single step S4b2, but this is not a limitation. The second insulating layer formation step at which the second insulating layer 6 is formed and the second gate electrode formation step may be performed as different steps. According to the present embodiment, the first oxide semiconductor layer OX that is included in the first transistor T1 and the second oxide semiconductor layer OX that is included in the second transistor T2 are composed of an In—Ga—Zn—O semiconductor material with, for example, a film thickness of about 30 nm but are not limited thereto. According to the present embodiment, the second insulating layer 6 is composed of, for example, a silicon oxide film having a film thickness of about 100 nm but is not limited thereto. According to the present embodiment, the second gate electrode G′ is composed of, for example, MoW having a film thickness of about 300 nm but is not limited thereto.

At the step S4c at which the first interlayer insulating film 7 that contains the conductor impurities is formed illustrated in FIG. 10, the first interlayer insulating film 7 that contains the conductor impurities is formed so as to be in contact with a portion of the second oxide semiconductor layer OX that is included in the second transistor T2 other than the second channel region CHR2 and the first-gate-electrode-combined first facing electrode G-CE1, and the first-gate-electrode-combined first facing electrode G-CE1 that contains the conductor impurities and the second source region SR2 and the second drain region DR2 that contain the conductor impurities are formed. According to the present embodiment, the first interlayer insulating film 7 that contains the conductor impurities is formed by using a silicon nitride film having, for example, a film thickness of about 160 nm but is not limited thereto. According to the present embodiment, the second facing electrode CE2 is formed by using, for example, MoW having a film thickness of about 100 nm but is not limited thereto.

According to the present embodiment, the second interlayer insulating film 8 that covers the second facing electrode CE2 and the first interlayer insulating film 7 is formed between the fifth step S5 and the sixth step S6 illustrated in FIG. 11, but this is not a limitation. The second interlayer insulating film 8 may not be formed. In particular, in the case where the multilayer film is used as the first interlayer insulating film 7, the second interlayer insulating film 8 may not be provided. According to the present embodiment, the second interlayer insulating film 8 is composed of, for example, a silicon oxide film having a film thickness of about 680 nm but is not limited thereto.

The sixth step S6 illustrated in FIG. 11 includes a contact hole formation step S6a at which a contact hole CON1 through which the second source region SR2 of the second transistor T2 is exposed, a contact hole CON2 through which the first source region SR1 of the first transistor T1 is exposed, and a contact hole CON3 through which the first drain region DR1 of the first transistor T1 is exposed are formed. The contact hole CON1 is formed in the first interlayer insulating film 7 and the second interlayer insulating film 8. The contact hole CON2 and the contact hole CON3 are formed in the first insulating layer 4, the first interlayer insulating film 7, and the second interlayer insulating film 8. The sixth step S6 illustrated in FIG. 11 further includes a step S6b at which the first drain electrode D that is electrically connected to the first drain region DR1, the first source electrode S that is electrically connected to the first source region SR1, and the second source electrode S′ that is electrically connected to the second source region SR2 are formed. According to the present embodiment, as illustrated at the step S6b in FIG. 11, the second facing electrode CE2 and the first source electrode S are electrically connected to each other by using the contact hole for electrically connecting the first source electrode S and the first source region SR1 to each other. Accordingly, the drive circuit substrate 1 enables the size of the first transistor T1 to be further reduced and enables each unit drive circuit DRU that includes the first transistor T1 to have higher definition. According to the present embodiment, the first drain electrode D, the first source electrode S, and the second source electrode S′ are composed of, for example, a multilayer film of a Ti film having a film thickness of about 30 nm, an Al film having a film thickness of about 300 nm, and a Ti film having a film thickness of about 20 nm but are not limited thereto.

At the seventh step S7 at which the passivation film 9 is formed illustrated in FIG. 12, the passivation film 9 is composed of, for example, a silicon nitride film having a film thickness of about 300 nm but is not limited thereto.

At the fourth step S4 illustrated in FIG. 10, that is, at the oxide semiconductor layer formation step S4a and the first interlayer insulating film formation step S4c, the second drain region DR2 and the first-gate-electrode-combined first facing electrode G-CE1 may be formed so as to be connected to each other. Consequently, a connection contact hole for electrically connecting the second drain region DR2 that the second transistor T2 has and the first-gate-electrode-combined first facing electrode G-CE1 that is included in the first transistor T1 to each other may not be provided. Accordingly, each unit drive circuit DRU that includes the first transistor T1 and the second transistor T2 can be formed with a reduced size, and each unit drive circuit DRU that includes the first transistor T1 and the second transistor T2 can have high definition, as for the drive circuit substrate 1.

At the step S4c at which the first interlayer insulating film 7 that contains the conductor impurities is formed illustrated in FIG. 10, a single-layer film composed of silicon nitride, silicon oxynitride, or silicon oxide or a multilayer film that includes two or more films among a silicon nitride film, a silicon oxynitride film, and a silicon oxide film may be formed as the first interlayer insulating film 7.

The second insulating layer 6 that is formed at the fourth step S4 illustrated in FIG. 10 may be composed of a silicon oxide film, and at the step S4c at which the first interlayer insulating film 7 that contains the conductor impurities is formed illustrated in FIG. 10, the first interlayer insulating film 7 may be composed of a single-layer film composed of silicon nitride or a multilayer film that includes a silicon nitride film that serves as a bottom layer.

In the method of manufacturing the drive circuit substrate 100 in the first comparative example illustrated in FIG. 16 and FIG. 17, as illustrated in FIG. 13, the first semiconductor layer 93 and the second semiconductor layer 93′ illustrated in FIG. 17 can be formed by performing a step S101 at which the first gate electrode G of the first transistor T1r and the second gate electrode G′ of the second transistor T2r are formed, and a step S102 at which injection LDP of impurities at a low concentration is performed with the first gate electrode G and the second gate electrode G′ used as masks and set up a lowly doped region LDR, and a step S103 at which injection HDP of impurities at a high concentration is performed with a resist film RM′ used as a mask. In the method of manufacturing the drive circuit substrate 1 according to the present embodiment, the first semiconductor layer 3 of the first transistor T1 and the second semiconductor layer 5b of the second transistor T2 can be formed by performing the third step S3 illustrated in FIG. 9, the oxide semiconductor layer formation step S4a illustrated in FIG. 10, the step S4b at which the second insulating layer 6 is formed, and the second gate electrode G′ is formed on the second insulating layer 6 illustrated in FIG. 10, and the step S4c at which the first interlayer insulating film 7 that contains the conductor impurities is formed illustrated in FIG. 10. The step S4c at which the first interlayer insulating film 7 that contains the conductor impurities is formed corresponds to a step at which the interlayer insulating film 15 is formed in the method of manufacturing the drive circuit substrate 100 in the first comparative example. Accordingly, as for the method of manufacturing the drive circuit substrate 1 according to the present embodiment, the steps are neither increased nor reduced in comparison with the method of manufacturing the drive circuit substrate 100 in the first comparative example, and the first semiconductor layer 3 of the first transistor T1 and the second semiconductor layer 5b of the second transistor T2 can be formed.

In the case of the N-type transistor that has the first channel region CHR1 that is the polycrystalline silicon layer, and the first drain region DR1 and the first source region SR1 that are the polycrystalline silicon layer that contains the N-type impurities, the degree of degradation is higher than the P-type transistor that has the first channel region CHR1 that is the polycrystalline silicon layer, and the first drain region DR1 and the first source region SR1 that are the polycrystalline silicon layer that contains the P-type impurities, and a channel length is increased to reduce the degree of degradation. As a result, the area is increased, which is a demerit. In contrast, in the case of the P-type transistor described above, the degree of degradation is low, and accordingly, the channel length can be reduced. As a result, the area can be reduced, which is a merit. In view of this, according to the present embodiment, the use of the P-type transistor that includes the holding capacitor Cs as the first transistor T1 that is included in each unit drive circuit DRU of the drive circuit substrate 1 achieves the drive circuit substrate 1 that enables the high definition and high reliability of each unit drive circuit DRU to be ensured.

Each unit drive circuit DRU of the drive circuit substrate 1 may include the first transistor T1 that includes the holding capacitor Cs and that is the P-type transistor and the second transistor T2 that includes the oxide semiconductor layer and that is the N-type transistor. With this structure, a CMOS structure obtained by combining the first transistor T1 that includes the polycrystalline silicon layer and that is the P-type transistor and the second transistor T2 that includes the oxide semiconductor layer and that is the N-type transistor can be achieved in each unit drive circuit DRU of the drive circuit substrate 1. In the case where the multiple unit drive circuits DRU each of which has the CMOS structure are provided in, for example, a non-display region of a display device and are used as a drive driver that drives a pixel circuit, a waveform inverting signal is more easily generated than a single channel circuit that includes a P-type transistor or an N-type transistor, the number of transistors to be provided can be reduced over the entire peripheral circuit of the display device, and the non-display region of the display device, that is, a peripheral region of the display device can have a narrow bezel.

In addition, the first transistor T1 that includes the polycrystalline silicon layer and that is the P-type transistor and the second transistor T2 that includes the oxide semiconductor layer and that is the N-type transistor may be combined into a demultiplexer (DEMUX) in each unit drive circuit DRU of the drive circuit substrate 1. With this structure, the drive voltage of the demultiplexer (DEMUX) can be reduced, and power consumption can be reduced. For example, in the case where the demultiplexer (DEMUX) includes only the second transistor T2 that includes the oxide semiconductor layer and that is the N-type transistor, for example, in the case where a video voltage range is 0 V to 5 V, the drive is ensured at VDL/VDH=0 V/10 V. In the case where the first transistor T1 that includes the polycrystalline silicon layer and that is the P-type transistor and the second transistor T2 that includes the oxide semiconductor layer and that is the N-type transistor are combined into a demultiplexer (DEMUX), for example, in the case where the video voltage range is 0 V to 5 V, the drive is ensured at VDL/VDH=0 V/5 V.

### Second Embodiment

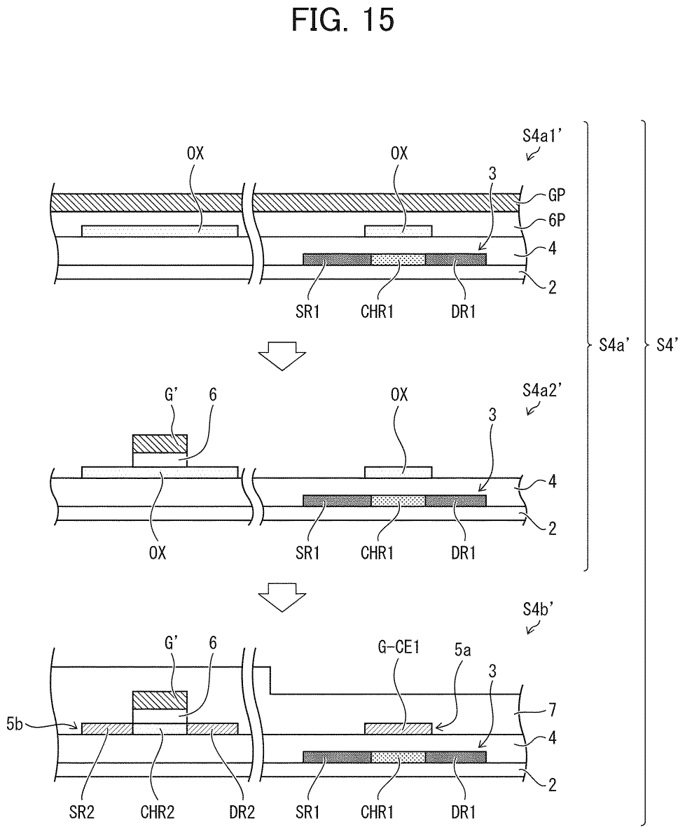

FIG. 14 illustrates some processes in a method of manufacturing a drive circuit substrate according to a second embodiment. FIG. 15 illustrates other processes in the method of manufacturing the drive circuit substrate according to the second embodiment.

The first step S1 at which the polycrystalline silicon layer PS′ is formed, the second step at which the first insulating layer 4 is formed on the polycrystalline silicon layer PS′, the fifth step S5 at which the second facing electrode CE2 is formed on the first interlayer insulating film 7 so as to overlap the first-gate-electrode-combined first facing electrode G-CE1 in plan view, and the sixth step S6 at which the first drain electrode D that is electrically connected to the first drain region DR1 and the first source electrode S that is electrically connected to the first source region SR1 and the second facing electrode CE2 are formed are the same as those according to the first embodiment described above, and the description thereof is omitted here.

According to the present embodiment, a third step S3′ illustrated in FIG. 14 and a fourth step S4′ illustrated in FIG. 15 described later are performed instead of the third step S3 and the fourth step S4 described according to the first embodiment.

The third step S3′ illustrated in FIG. 14 includes an oxide semiconductor layer formation step at which the first oxide semiconductor layer OX is formed on the first insulating layer 4 so as to overlap a portion of the polycrystalline silicon layer in plan view, and a step S3b′ at which the resist film RM is formed on the first oxide semiconductor layer OX, P-type impurities are injected into a portion other than the portion of the polycrystalline silicon layer with the resist film RM used as a mask, and consequently, the first channel region CHR1, the first source region SR1 that contains the P-type impurities, and the first drain region DR1 that contains the P-type impurities are formed. As illustrated in FIG. 14, the oxide semiconductor layer formation step described above includes a step S3a′ at which an oxide semiconductor layer OXP is formed on the entire surface of the first insulating layer 4, and a step at which the oxide semiconductor layer OXP that is formed on the entire surface of the first insulating layer 4 is etched by using the resist film RM, and the first oxide semiconductor layer OX is obtained.

The fourth step S4′ illustrated in FIG. 15 is a step at which the first-gate-electrode-combined first facing electrode G-CE1 is formed, and the step includes a first interlayer insulating film formation step at which the first interlayer insulating film 7 that contains the conductor impurities is formed on the first insulating layer 4 and the first oxide semiconductor layer OX after the resist film RM is removed. A step S4a′ that includes a step S4al′ and a step S4a2′ illustrated in FIG. 15 is the same as the step S4b that includes the step S4b1 and the step S4b2 illustrated in FIG. 10, and the description thereof is omitted. The step S4b′ illustrated in FIG. 15 is the same as the step S4c illustrated in FIG. 10, and the description thereof is omitted.

The present disclosure can be used for a drive circuit substrate and a method of manufacturing a drive circuit substrate.

The present disclosure contains subject matter related to that disclosed in Japanese Priority Patent Application JP 2024-022199 filed in the Japan Patent Office on Feb. 16, 2024, the entire contents of which are hereby incorporated by reference.

It should be understood by those skilled in the art that various modifications, combinations, sub-combinations and alterations may occur depending on design requirements and other factors insofar as they are within the scope of the appended claims or the equivalents thereof.

What is claimed is:

1. A drive circuit substrate comprising:
a unit drive circuit including a first transistor including:
a first semiconductor layer having a first channel region that is a portion of a polycrystalline silicon layer, and a first source region and a first drain region that are formed as regions of the polycrystalline silicon layer different from the first channel region and that contain a P-type impurity;
a first insulating layer that is provided on the first semiconductor layer;
a first-gate-electrode-combined first facing electrode that contains an oxide semiconductor and a conductor impurity and that is provided on the first insulating layer such that the first-gate-electrode-combined first facing electrode overlaps the first channel region in plan view;
a first interlayer insulating film that is provided on the first-gate-electrode-combined first facing electrode;
a second facing electrode that is provided on the first interlayer insulating film such that the second facing electrode overlaps the first-gate-electrode-combined first facing electrode in plan view;
a first drain electrode that is electrically connected to the first drain region;
a first source electrode that is electrically connected to the first source region and the second facing electrode; and
a holding capacitor that includes the first facing electrode and the second facing electrode.

2. The drive circuit substrate according to claim 1,
wherein the unit drive circuit includes a second transistor,
wherein the second transistor includes:
a second semiconductor layer having a second channel region, a second source region, and a second drain region;
a second insulating layer that is provided on the second channel region such that the second insulating layer overlaps only the second channel region in plan view;
a second gate electrode that is provided on the second insulating layer such that the second gate electrode overlaps the second channel region in plan view; and
a second source electrode that is electrically connected to the second source region,
wherein the second channel region is formed in the same layer as the first-gate-electrode-combined first facing electrode and is composed of the same material as the oxide semiconductor, and
wherein the second source region and the second drain region are formed in the same layer as the first-gate-electrode-combined first facing electrode and are composed of the same material as the first-gate-electrode-combined first facing electrode.

3. The drive circuit substrate according to claim 2,
wherein the first interlayer insulating film contains the conductor impurity,
wherein the first interlayer insulating film is provided on the second source region, the second drain region, and the first-gate-electrode-combined first facing electrode and is in contact with the second source region, the second drain region, and the first-gate-electrode-combined first facing electrode, and
wherein the first interlayer insulating film is not in contact with the second channel region.

4. The drive circuit substrate according to claim 3,
wherein the first interlayer insulating film is a single-layer film composed of silicon nitride, silicon oxynitride, or silicon oxide or a multilayer film that includes two or more films among a silicon nitride film, a silicon oxynitride film, and a silicon oxide film.

5. The drive circuit substrate according to claim 3,
wherein the second insulating layer is a silicon oxide film, and
wherein the first interlayer insulating film is a single-layer film composed of silicon nitride or a multilayer film that includes a silicon nitride film that serves as a bottom layer.

6. The drive circuit substrate according to claim 2,
wherein the second drain region and the first-gate-electrode-combined first facing electrode are connected to each other.

7. A method of manufacturing a drive circuit substrate, the method comprising:
forming a polycrystalline silicon layer;
forming a first insulating layer on the polycrystalline silicon layer;
forming a first channel region, a first source region that contains a P-type impurity, and a first drain region that contains the P-type impurity by forming a resist film that has a predetermined shape on the first insulating layer and injecting the P-type impurity into a portion of the polycrystalline silicon layer with the resist film used as a mask;
forming a first-gate-electrode-combined first facing electrode, wherein after the resist film is removed, a first oxide semiconductor layer is formed on the first insulating layer such that the first oxide semiconductor layer overlaps the first channel region in plan view, and a first interlayer insulating film that contains a conductor impurity is formed on the first insulating layer and the first oxide semiconductor layer;
forming a second facing electrode on the first interlayer insulating film such that the second facing electrode overlaps the first-gate-electrode-combined first facing electrode in plan view;
forming a first drain electrode that is electrically connected to the first drain region and a first source electrode that is electrically connected to the first source region and the second facing electrode; and
forming a unit drive circuit including a first transistor including a holding capacitor that includes the first facing electrode and the second facing electrode.

8. A method of manufacturing a drive circuit substrate, the method comprising:
forming a polycrystalline silicon layer;
forming a first insulating layer on the polycrystalline silicon layer;
forming a first oxide semiconductor layer on the first insulating layer such that the first oxide semiconductor layer overlaps a portion of the polycrystalline silicon layer in plan view and forming a first channel region, a first source region that contains a P-type impurity, and a first drain region that contains the P-type impurity by forming a resist film on the first oxide semiconductor layer and injecting the P-type impurity into a portion other than the portion of the polycrystalline silicon layer with the resist film used as a mask;
forming a first-gate-electrode-combined first facing electrode, wherein after the resist film is removed, a first interlayer insulating film that contains a conductor impurity is formed on the first insulating layer and the first oxide semiconductor layer;
forming a second facing electrode on the first interlayer insulating film such that the second facing electrode overlaps the first-gate-electrode-combined first facing electrode in plan view;
forming a first drain electrode that is electrically connected to the first drain region and a first source electrode that is electrically connected to the first source region and the second facing electrode; and
forming a unit drive circuit including a first transistor including a holding capacitor that includes the first facing electrode and the second facing electrode.

9. The method according to claim 7,
wherein forming the first insulating layer includes forming the first insulating layer on a portion other than the polycrystalline silicon layer,
wherein forming the first oxide semiconductor layer includes forming the first oxide semiconductor layer that is included in the first transistor and a second oxide semiconductor layer that is included in a second transistor on the first insulating layer as the same layer by using the same material,
wherein between forming the first oxide semiconductor layer and forming the first interlayer insulating film, a second insulating layer is formed so as to overlap only a portion of the second oxide semiconductor layer that is included in the second transistor and that is a second channel region in plan view, and a second gate electrode is formed on the second insulating layer so as to overlap the second channel region in plan view, and
wherein forming the first interlayer insulating film includes forming the first interlayer insulating film such that the first interlayer insulating film is in contact with a portion of the second oxide semiconductor layer that is included in the second transistor other than the second channel region and the first-gate-electrode-combined first facing electrode and forming the first-gate-electrode-combined first facing electrode that contains the conductor impurity and a second source region and a second drain region that contain the conductor impurity.

10. The method according to claim 9,
wherein forming the first oxide semiconductor layer and forming the first interlayer insulating film include forming the second drain region and the first-gate-electrode-combined first facing electrode that are connected to each other.

11. The method according to claim 10,
wherein forming the first interlayer insulating film includes forming, as the first interlayer insulating film, a single-layer film composed of silicon nitride, silicon oxynitride, or silicon oxide or a multilayer film that includes two or more films among a silicon nitride film, a silicon oxynitride film, and a silicon oxide film.

12. The method according to claim 10,
wherein forming the second insulating layer includes forming, as the second insulating layer, a silicon oxide film, and
wherein forming the first interlayer insulating film includes forming, as the first interlayer insulating film, a single-layer film composed of silicon nitride or a multilayer film that includes a silicon nitride film that serves as a bottom layer.
